(19) United States
(12) Patent Application Publication
(10) Pub. No.: US 2008/0315198 A1
(43) Pub. Date: Dec. 25, 2008

(54) IMAGE SENSOR AND METHOD FOR MANUFACTURING THE SAME

(76) Inventor: Oh Jin Jung, Gyeonggi-do (KR)

Correspondence Address: SHERR & VAUGHN, PLLC, 620 HERNDON PARKWAY, SUITE 200, HERNDON, VA, 20170, US

(21) Appl. No.: 11/967,380

(22) Filed: Dec. 31, 2007

(30) Foreign Application Priority Data
Jun. 25, 2007 (KR) 10-2007-0062009

(51) Int. Cl. H01L 21/329; H01L 31/00

(52) U.S. Cl. 257/53; 257/458; 438/59; 257/E31.113; 257/E21.352

(57) ABSTRACT

An image sensor and a manufacturing method thereof are provided. The sensor includes a substrate, a bottom electrode, an intrinsic layer and a first conductive layer formed over the substrate, a diffusion barrier film formed over the first conductive layer, and an upper transparent electrode formed over the diffusion barrier film. Therefore, a vertical integration of a transistor circuitry and a photodiode can be provided. Further, the leakage current is prevented and the photosensitivity is increased by performing the plasma treatment on the first conductive layer. Due to the vertically integrated transistor circuitry and photodiode, the fill factor can approach 100%, and higher sensitivity compared with the related art having the same pixel size can be provided. The sensitivity of each unit pixel is not reduced, even though more complex circuitry is realized on the image sensor.

The present application claims priority under 35 U.S.C. 119 to Korean Patent Application No. 10-2007-0062009, filed on Jun. 25, 2007, which is hereby incorporated by reference in its entirety.

### BACKGROUND

Image sensors, which are semiconductor devices for converting an optical image into an electrical signal, may be categorized as charge coupled device (CCD) image sensors and complementary metal oxide silicon (CMOS) image sensors.

CCDs have disadvantages. These include complicated driving requirements, relatively high power consumption, and a complicated manufacturing process which requires a multi-stage photolithography process. As a next generation image sensor for overcoming the disadvantages of CCDs, CMOS image sensors have attracted interest.

CMOS image sensors use a photo diode and a MOS transistor in each unit pixel. Images are detected by sequentially detecting the electrical signals from each unit pixel. CMOS image sensors according to the related art can be divided into a photo diode region for receiving light signals and changing them into electrical signals, and a transistor region for processing the electrical signals. However, the CMOS image sensor according to the related art uses a structure having the photo diode horizontally arranged with the transistor.

So while the disadvantages of the CCD image sensor have been reduced by the horizontal type CMOS image sensor, the horizontal type CMOS image sensor according to the related art still has problems. In other words, in the planar CMOS image sensor according to the related art, the photo diode and the transistor are manufactured to be horizontally adjacent to each other on the substrate. Accordingly, additional area is required to accommodate both the photo diode and the transistor. As a result, fill factor (the percentage of the area filled by photosensitive regions) may be reduced, and higher resolutions may be limited.

In the planar CMOS image sensor according to the related art, it is very difficult to simultaneously optimize the manufacturing processes of the photo diode and the transistor. For example, in the transistor process, a shallow junction for low sheet resistance is required; however, in the photo diode process, such a shallow junction may not be proper.

In a planar CMOS image sensor according to the related art, as additional on-chip functions are integrated onto the image sensor, the size of the unit pixel may be increased for maintaining the photosensitivity of the image sensor, or the area for the photo diode may be reduced for maintaining a pixel size. If the unit pixel size is increased the resolution of the image sensor is reduced. If the area of the photo diode is reduced to maintain unit pixel size, the photosensitivity of the image sensor is reduced.

### SUMMARY

Embodiments relate to an image sensor capable of providing enhanced integration of transistor circuitry and photodiodes, including a method for manufacturing the image sensor. Embodiments relate to an image sensor capable of minimizing leakage current, including a method for manufacturing the image sensor. Embodiments relate to an image sensor which maximizes resolution and sensitivity at the same time, including a method for manufacturing the image sensor. Embodiments relate to an image sensor which minimizes defects within a photodiode, using the vertical photodiode structure, including a method for manufacturing the image sensor.

Embodiments relate to an image sensor which includes a substrate including at least one circuit element, a bottom electrode, an intrinsic layer and a first conductive layer sequentially formed over the substrate, a diffusion barrier film formed over the first conductive layer, and an upper transparent electrode formed over the diffusion barrier film. Embodiments relate to a method for manufacturing an image sensor which includes, forming a bottom electrode, an intrinsic layer, and a first conductive layer sequentially over a substrate including at least one circuit element, forming a diffusion barrier film over the first conductive layer, and forming an upper transparent electrode over the diffusion barrier film.

### DRAWINGS

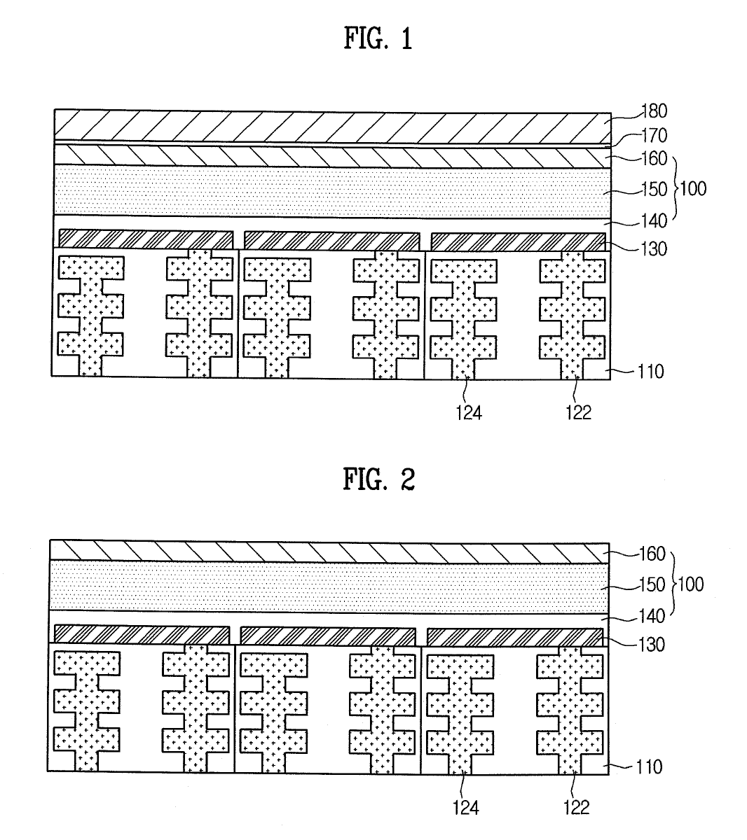

Example FIG. 1 is a sectional view illustrating an image sensor according to embodiments.

Example FIGS. 2 to 5 are sectional views illustrating a method for manufacturing an image sensor according to embodiments.

### DESCRIPTION

Example FIG. 1 is a sectional view of an image sensor according to embodiments.

The image sensor according to embodiments includes: a substrate 110 including at least one circuit element, a bottom electrode 130, an intrinsic layer 150, and a first conductive layer 160 sequentially formed over the substrate 110. A diffusion barrier film 170 is formed over the first conductive layer 160, and an upper transparent electrode 180 formed over the diffusion barrier film 170.

The image sensor may provide a vertical integration of a transistor circuitry and a photodiode. In embodiments, a diffusion barrier film 170 is formed over a conductive layer 160 by performing a plasma treatment or the like to prevent the leakage current. For example, the diffusion barrier film 170 may be an N-rich first conductive layer. For example, the diffusion barrier film 170 may be a layer where nitrogen is diffused on the first conductive layer. Also, for example, the diffusion barrier film 170 may be formed by performing a plasma treatment or the like. By having an oxygen concentration of 60% or less, the oxygen in the upper transparent electrode 180 may be prevented from diffusing into the inside of a photodiode 100.

The image sensor according to embodiments may further include metal wiring 124, electron transfer wiring 122, and a second conductive layer 140. The layers including the second conductive layer 140, intrinsic layer 150 and first conductive layer 160 can be referred to as a photodiode 100. Here, the first conductive layer 160 may be a first conductive type, and the second conductive layer 140 may be a second conductive type. Also, the first conductive type may be opposite to the second conductive type.

A method for manufacturing an image sensor according to embodiments will be described with reference to example FIGS. 2 to 5. First, as shown in example FIG. 2, a bottom electrode 130, an intrinsic layer 150, and a first conductive layer 160 are sequentially formed over a substrate 110 which includes at least one circuit element.

Inside the substrate 110, metal wiring 124 and electron transfer wiring 122 may be formed. The bottom electrode 130 may be formed with various conductive materials including, for example, metals, alloys, or silicides. For example, the bottom electrode 130 may be formed by depositing a metal such as Cr, Ti, TiW or Ta, which can easily form a silicide, using a PVD (physical vapor disposition) method.

In embodiments, a barrier metal may be formed between the electron transfer wiring 122 and bottom electrode 130. The barrier metal may be formed with tungsten, titanium, tantalum or a nitride thereof. As a matter of course, the barrier metal may also not be formed.

Next, a second conductive layer 140 may be formed over the bottom electrode 130. If necessary, the subsequent processes may also be carried out without forming the second conductive layer 140. The second conductive layer 140 may serve as an N layer of the PIN diode which is employed embodiments according to example FIG. 1. That is, the second conductive layer 140 may be an N-type conductive layer, but it is not limited thereto.

The second conductive layer 140 may be formed using n-doped amorphous silicon, but it is not limited thereto. That is, the second conductive layer 140 may also be formed into a-Si:H, a-SiGe:H, a-SiC, a-SiN:H, or a-SiO:H by adding germanium, carbon, nitrogen, or oxygen to amorphous silicon. The second conductive layer 140 may be formed by a chemical vapor deposition (CVD), i.e., a PECVD (plasma-enhanced chemical vapor deposition). For example, the second conductive layer 140 may be formed as amorphous silicon by combining a silane gas (SiH₄) with PH₃, P₂H₅ or the like via the PECVD.

Next, an intrinsic layer 150 may be formed over the substrate 110 including the second conductive layer 140. The intrinsic layer 150 serves as an I layer of the PIN diode which is employed in the embodiment. The intrinsic layer 150 may be formed using amorphous silicon. The intrinsic layer 150 may be formed by a chemical vapor deposition (CVD), i.e., PECVD. For example, the intrinsic layer 150 may be formed with amorphous silicon using silane gas (SiH₄) or the like via PECVD.

Thereafter, a first conductive layer 160 is formed over the intrinsic layer 150. The first conductive layer 160 may be formed in a sequential process with the intrinsic layer 150. The first conductive layer 160 serves as a P layer of the PIN diode. That is, the first conductive layer 160 may be a P-type conductive layer, but it is not limited thereto. The first conductive layer 160 may be formed using p-doped amorphous silicon, but it is not limited thereto. The first conductive layer 160 may be formed by a chemical vapor deposition (CVD), particularly, PECVD or the like. For example, the first conductive layer 160 may be formed into amorphous silicon by combining a silane gas (SiH₄) with boron or the like via the PECVD.

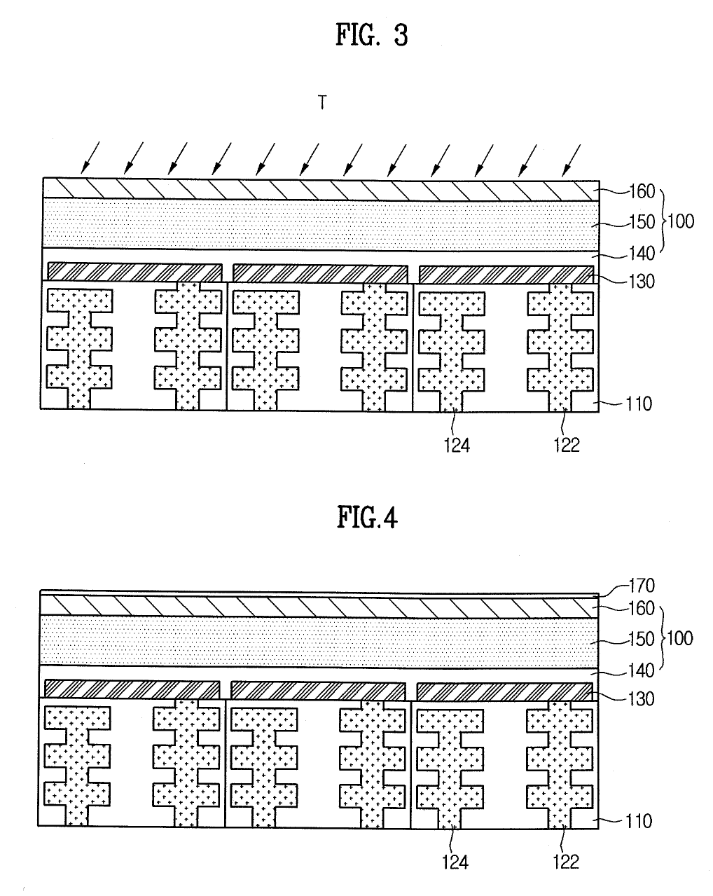

Next, a diffusion barrier film 170 (refer to example FIG. 4) is formed over the first conductive layer 160. As an example of a method for forming the diffusion barrier film 170, the surface of the first conductive layer 160 as shown in example FIG. 3 is subjected to a plasma treatment (T) to form a diffusion barrier 170 over the first conductive layer 160 as shown in example FIG. 4. For example, the plasma treatment (T) may be carried out using N₂ gas at a temperature of approximately 100° C. to 400° C. and a pressure of about 10 mtorr to 100 mtorr, thereby forming a thin, N-rich, P-doped a-Si:H layer 170. The layer thus formed may serve as a diffusion barrier film against oxygen in an upper transparent electrode 180 to be described later. The diffusion barrier film can be effective against oxygen diffusion by having a concentration of oxygen in the diffusion barrier film 170 of 60% or less.

In another method for forming the diffusion barrier film 170, a gas cluster ion beam treatment may be performed to form a diffusion barrier film 170 over the first conductive layer 160. For example, using a gas cluster ion beam treatment, a gas cluster ion beam with a scale of approximately 100 to 9,000 μm is formed using N₂ gas. Using the gas cluster ion beam, the diffusion barrier film 170 is formed over the first conductive layer 160. The diffusion barrier film 170 may limit oxygen diffusion by having an oxygen concentration of 60% or less.

The gas cluster ions employed in the above-described second method are N ions clustered at a low energy state, which is different from the individual beam of N ions. Thus, the gas cluster ions have a relatively high weight, and they collide with the surface of the conductive layer 160. Therefore, the gas cluster ions a have limited effect only on the surface of the conductive layer 160 and can minimize the surface damage, thereby forming the diffusion barrier film 170.

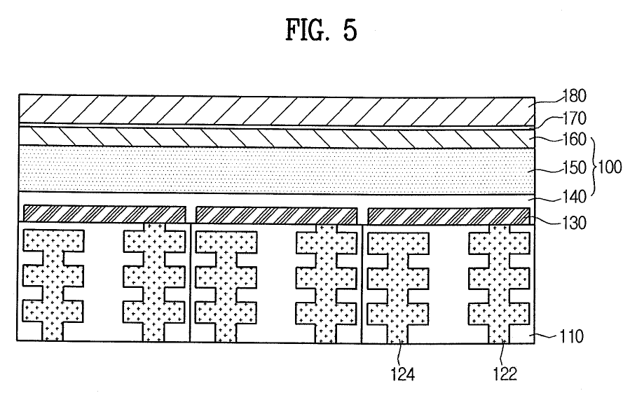

Then, an upper transparent electrode 180 may be formed over the diffusion barrier film 170 as shown in example FIG. 5. The upper transparent electrode 180 may have high light transmission and conductivity. For example, the upper transparent electrode 180 may be formed with ITO (indium tin oxide), CTO (cadmium tin oxide) or the like. However, the oxygen component in the upper transparent electrode 180 may diffuse into the intrinsic layer 150 so that the leakage current may increase and the photosensitivity characteristics may deteriorate. Therefore, in the method for manufacturing an image sensor according to embodiments, the diffusion barrier film 170 is formed over the first conductive type layer 160 by the plasma treatment or gas cluster ion beam treatment. As a result, the diffusion barrier film 170 prevents the oxygen in the upper transparent electrode 180 from diffusing. This results in minimized leakage current and a relative increase in photosensitivity.

The image sensor and the method for manufacturing the same according to embodiments may provide a structure where transistor circuitry and a photo diode are vertically integrated. Further, the leakage current is minimized and the photosensitivity is increased by performing the plasma treatment over the first conductive layer. The vertically integrated transistor circuitry and photodiode provides a fill factor which may approach 100%. Compared with the related art, higher sensitivity can be provided with the same pixel size. The process cost for the same resolution can be reduced compared with the related art. The sensitivity of each unit pixel is not reduced, even though more complex circuitry is realized on the image sensor. Moreover, additional on-chip functions that can be integrated in embodiments can increase performance of the image sensor. Miniaturization of a device and reduction in the production cost can be achieved. Furthermore, defects inside the photodiode can be prevented by employing the vertically integrated photodiode.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. An apparatus comprising:
a substrate having at least one circuit element;
a bottom electrode, an intrinsic layer, a first conductive layer sequentially formed over the substrate;
a diffusion barrier film formed over the first conductive layer; and
an upper transparent electrode formed over the diffusion barrier film.

2. The apparatus of claim 1, wherein the diffusion barrier film has an oxygen concentration of approximately 60% or less.

3. The apparatus of claim 1, wherein the diffusion barrier film is a layer having nitrogen diffused on the first conductive layer.

4. The apparatus of claim 1, comprising a second conductive layer formed between the bottom electrode and the intrinsic layer.

5. The apparatus of claim 1, wherein the substrate includes metal wiring and electron transfer wiring.

6. The apparatus of claim 1, wherein said substrate comprises transistor circuitry vertically integrated with said bottom electrode, intrinsic layer, first conductive layer, diffusion barrier, and upper electrode.

7. The apparatus of claim 1, wherein said bottom electrode, intrinsic layer, and first conductive layer form a PIN diode.

8. The apparatus of claim 1, wherein said first conductive layer is amorphous silicon.

9. A method comprising:
forming a bottom electrode, an intrinsic layer, and a first conductive layer sequentially over a substrate including at least one circuit element;
forming a diffusion barrier film over the first conductive layer; and
forming an upper transparent electrode over the diffusion barrier film.

10. The method of claim 9, wherein the diffusion barrier film is formed over the first conductive layer by performing a plasma treatment on the surface of the first conductive layer.

11. The method of claim 10, wherein the plasma treatment is carried out using N₂ gas at a temperature of approximately 100° C. to 400° C.

12. The method of claim 11, wherein the plasma treatment is carried out using N₂ gas at a pressure of 10 mtorr to 100 mtorr.

13. The method of claim 9, wherein the diffusion barrier film is formed over the first conductive layer by performing a gas cluster ion beam treatment.

14. The method of claim 9, wherein the gas cluster ion beam treatment is carried out by using a gas cluster ion beam with a scale of approximately 100 to 9,000 microns formed using N₂ gas, to form the diffusion barrier film over the first conductive layer.

15. The method of claim 9, wherein the diffusion barrier film has an oxygen concentration of approximately 60% or less.

16. The method of claim 9, comprising forming a second conductive layer over the bottom electrode, and forming the intrinsic layer over the second conductive layer.

17. The method of claim 9, comprising forming electron transfer wiring inside the substrate.

18. The method of claim 17, comprising forming a barrier metal between the electron transfer wiring and the bottom electrode.

19. The method of claim 9, comprising vertically integrating transistor circuitry with said bottom electrode, intrinsic layer, first conductive layer, diffusion barrier, and upper electrode.

20. The method of claim 9, comprising forming a PIN diode from said bottom electrode, intrinsic layer, and first conductive layer.
